(19) United States
(12) Patent Application Publication
(10) Pub. No.: US 2024/0162382 A1
(43) Pub. Date: May 16, 2024

(54) LIGHT-EMITTING PACKAGE AND LIGHT-EMITTING ELEMENT

(71) Applicant: EPISTAR CORPORATION, Hsinchu (TW)

(72) Inventors: Wu-Tsung LO, Hsinchu (TW); Chih-Hao CHEN, Hsinchu (TW); Wei-Che WU, Hsinchu (TW); Heng-Ying CHO, Hsinchu (TW); Tsun-Kai KO, Hsinchu (TW)

(21) Appl. No.: 18/506,698

(22) Filed: Nov. 10, 2023

(30) Foreign Application Priority Data
Nov. 14, 2022 (TW) 111143379

(51) Int. Cl. H01L 33/22; H01L 33/10; H01L 33/62

(52) U.S. Cl. CPC H01L 33/22; H01L 33/10; H01L 33/62

(57) ABSTRACT

The present disclosure provides a light-emitting package. The light-emitting package includes a main body, a cavity disposed in the cavity, a base plane in the cavity and a light-emitting element. The light-emitting element is disposed in the cavity and connected to the base plane. The light-emitting element includes a substrate and a semiconductor stack on the substrate. The substrate includes a side wall, and the side wall incudes a first cutting trace. The main body includes a step portion disposed in the cavity and it surrounds the light-emitting element. The step portion comprises a first height relative to base plane, and the first cutting trace comprises a second height relative to the base plane. The second height is greater than the first height.

### CROSS REFERENCE TO RELATED APPLICATIONS

This application claims priority to the benefit of Taiwan Patent Application Number 111143379 filed on Nov. 14, 2022 and the entire contents of which are hereby incorporated by reference herein in their entireties.

### TECHNICAL FIELD

The present disclosure relates to a light-emitting package, and more particularly, to a light-emitting element of a light-emitting package having cutting trace.

### DESCRIPTION OF BACKGROUND ART

Light-emitting diodes (LEDs) is a kind of light-emitting element, which can emit various colors of light when electric voltage is applied. Recently, nitride-based light-emitting diodes are commonly used for semiconductor optical device which generates blue or green light. Considering the condition of lattice match of compounds, nitride-based semiconductor material is generally grown on the sapphire substrate, and then electrode structures are formed to form the nitride-based light-emitting diode. Traditionally, to the light-emitting package manufactured by wire bonding, the electrode structures of the light-emitting diode may block a portion of light, so the luminous efficiency of the light-emitting diode is reduced.

In the development history of light-emitting elements and light-emitting packages, to satisfy the need of different application and achieve higher productivity, the manufacturing process of the light-emitting element along with its package encounter many unresolved problems. Although the current light-emitting elements and the light-emitting packages prevalently meet the requirement, not all of the aspects are satisfying. Therefore, there is still a need to improve the structure of the light-emitting element and the light-emitting package to meet the product needs.

### SUMMARY OF THE APPLICATION

According to some embodiments of the present disclosure, a light-emitting package is provided. The light-emitting package includes a main body, a cavity disposed in the cavity, a base plane in the cavity, and a light-emitting element. The light-emitting element is disposed in the cavity and connected with the base plane. The light-emitting element comprises a substrate and a semiconductor stack on the substrate. The substrate includes a side wall, and the side wall incudes a first cutting trace. The main body includes a first step portion disposed in the cavity and the first step portion surrounds the light-emitting element. The first step portion comprises a first height relative to the base plane and the first cutting trace comprises a second height relative to the base plane. The second height is greater than the first height.

According to other embodiments of the present disclosure, a light-emitting element is provided. The light-emitting element comprises a substrate, a semiconductor stack, a first insulting reflective layer, a second insulating reflective layer, and an electrode. The substrate comprises a first surface, a second surface opposite to the first surface, and a side wall. The semiconductor stack is disposed on the first surface. The first insulting reflective layer is disposed on the semiconductor stack and has an opening. The second insulating reflective layer is disposed on the second surface; The electrode is disposed on the first insulating reflective layer and filled in the opening to electrically connecting the semiconductor stack. The side wall comprises a first cutting trace, which is disposed at a height located in a range of forty percent to sixty percent thickness of the substrate relative to the bottom surface of the substrate.

### BRIEF DESCRIPTION OF THE DRAWINGS

The embodiments of the present application may be more fully understood by reading the subsequent detailed description and examples with references made to the accompanying drawings, wherein:

FIG. 1 illustrates a cross-sectional view of a light-emitting package in accordance with some embodiments.

FIG. 2 illustrates a partial enlargement view of FIG. 1 in accordance with some embodiments.

FIG. 3 illustrates a cross-sectional view of a light-emitting element in accordance with some embodiments.

FIG. 4 illustrates a cross-sectional view of the light-emitting package in accordance with some other embodiments.

FIG. 5 illustrates a partial enlargement view of FIG. 4 in accordance with some embodiments.

FIG. 6 illustrate a side view of the light-emitting element in accordance with some embodiments.

### DETAILED DESCRIPTION OF THE APPLICATION

The light-emitting package and light-emitting element of the embodiments of the present application are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

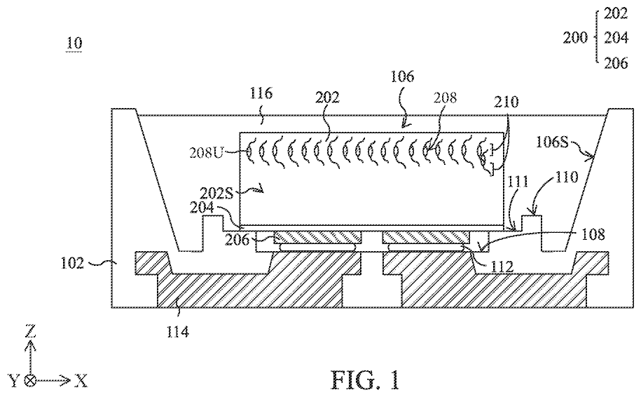

FIG. 1 illustrates a cross-sectional view of a light-emitting package 10 in accordance with some embodiments. Referring to FIG. 1, the light-emitting package 10 incudes a main body 102, a cavity 106, a base plane 108, an electric conducting structure 114, and a light-emitting element 200 disposed in the cavity 106. In addition to the cross-sectional view, FIG. 1 also illustrates the lateral appearance of the light-emitting element 200 disposed in the light-emitting package 10, including one of the side walls 202S of the light-emitting element 200.

The main body 102 of the light-emitting package 10 can reflect the light emitted by the light-emitting element 200 to a light-emitting surface of the light-emitting package 10, e.g., the topmost surface of the light-emitting package 10 along Z-axis direction, so as to enhance luminous efficiency of the light-emitting package 10. In detail, in some embodiments, the material of the main body 102 may comprise polyphthalamide (PPA), polyamide (PA), polytrimethylene terephthalate (PTT), polyethylene terephthalate (PET), polycyclohexylenedimethylene terephthalate (PCT), epoxy molding compound (EMC) material, sheet molding compound (SMC) material, or other suitable resin or ceramic material with high reflectivity. Specifically, in accordance with some embodiments, the high reflectivity material of the main body 102 can have a light reflectivity greater than 90% for the light with the wavelengths between 200 nm to 1100 nm.

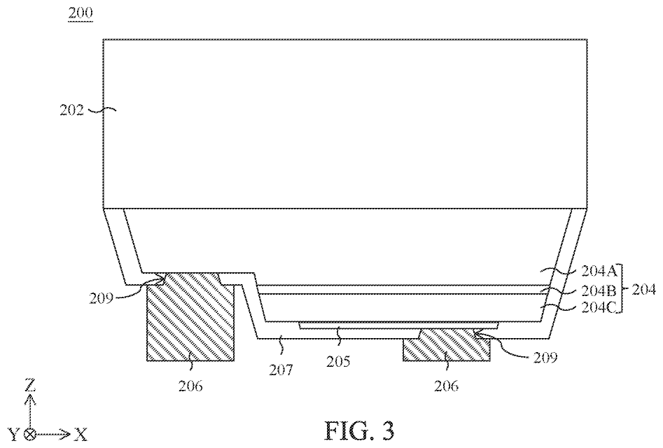

In FIG. 1, the main body 102 comprises the cavity 106, and the base plane 108 is disposed in the cavity 106. It is noted that the so-called “base plane” described in the specification is a bottommost surface of the cavity 106 of the light-emitting package 10. Further, the light-emitting element 200 is disposed in the cavity 106 and connected to the base plane 108. In one embodiment, as shown in FIG. 1, the light-emitting element 200 is connected to the base plane 108 in a manner of flip-chip. The light-emitting element 200 comprises a substrate 202 and a semiconductor stack 204 on the substrate 202. The detail composition of the light-emitting element 200 and its material will be further described hereunder with reference to FIG. 3.

According to some embodiments, the light-emitting element 200 further comprises electrodes 206, and the light-emitting element 200 may be connected to the base plane 108 via the electrodes 206. In detail, the electrodes 206 may be disposed between the base plane 108 and the semiconductor stack 204.

The substrate 202 of the light-emitting element 200 comprises a plurality of side walls 202S, and any one of the side walls 202S comprises a first cutting trace 208. FIG. 1 shows one of the side walls 202S. In some embodiments, in the manufacturing processes of the light-emitting element 200, after forming a plurality of light-emitting elements 200 on a wafer (not shown), laser beam (e.g., stealth dicing laser) may be focused in an interior of the substrate 202 to form a modified region along a predetermined dicing street in accordance with the shape and the size of the light-emitting element 200. In the following processes, dicing the wafer along the modified region to form the plurality of light-emitting elements 200 that is separated to each other. After forming each one of the independent light-emitting elements 200, the modified region of the substrate of the wafer is formed to be the first cutting trace 208 on the side wall 202S of the substrate 202 of each of the independent light-emitting elements 200. According to some embodiments, the first cutting trace 208 comprises a plurality of dotted cutting trace units 208U that is arranged along a horizontal direction (e.g., along the X-axis direction Y-axis direction in FIG. 1). In addition, the aforementioned dotted cutting trace units 208U may be separated and disconnected to each other or separated and connected to each other. In one embodiment, the adjacent dotted cutting trace units 208U are partially overlapped to render the plurality of the dotted cutting trace units 208U being connected.

Further, in accordance with some embodiments, after irradiating laser beam to the substrate of the wafer to form the first cutting trace and exerting force to fully separate the plurality of light-emitting elements 200, a roughened region 210 may be formed on a top side and/or a bottom side of the first cutting trace 208. The roughened region 210 is also disposed on the side wall 202S of the substrate 202 and adjacent to the first cutting trace 208. In one embodiment, as shown in FIG. 1, the roughened region 210 may be on the top side and the bottom side of the first cutting trace 208. In one embodiment, the roughened region 210 may be further disposed between the plurality of dotted cutting trace units 208U. In one embodiment, the roughened region 210 may be connected with the plurality of the dotted cutting trace units 208U.

Referring to FIG. 1 again, the main body 102 of the light-emitting package 10 comprises a step portion 110. The step portion 110 is disposed in the cavity 106 and surrounds the light-emitting element 200. In one embodiment, the step portion 110 is protruded from the base plane 108 and forms a height relative to the base plane 108, and the step portion 110 is integrally formed with the main body 102. In some embodiments, as shown in FIG. 1, the cavity 106 of the light-emitting package 10 comprises an inner wall 106S. The inner wall 106S is separated from the step portion 110.

In some embodiments, the light-emitting package 10 may further comprises a bonding layer 112. In one embodiment, the light-emitting element 200 may further be connected to the base plane 108 via the bonding layers 112. In addition, one of the electrodes 206 of the light-emitting element 200 is correspondent with one of the bonding layers 112, while the other electrode 206 is correspondent with the other bonding layer 112. Before the light-emitting element 200 connecting the base plane 108, the bonding layers 112 may be formed on the electrodes 206 respectively, formed on the base plane 108, or respectively formed on one of the electrodes 206 and the base plane 108 and then connecting the light-emitting element 200 to the base plane 108 by bonding process. According to some embodiments, the material of the bonding layer 112 may comprise solder or other eutectic metal, such as indium (In), nickel (Ni), copper (Cu), gold (Au), tin (Sn), aluminum (Al), or a stack or an alloy of the aforementioned materials.

The light-emitting package 10 comprises an electric conducting structure 114. In some embodiments, the electric conducting structure 114 is embedded in the main body 102. In addition, a part of the electric conducting structure 114 is exposed to the cavity 106 and parallel to the base plane 108. The part of the electric conducting structure 114 that is exposed may be used for physically connecting the light-emitting element 200 and for electric connecting an electric circuit outside the light-emitting element 200 and the light-emitting package 10. According to some embodiments, the light-emitting element 200 may be connected to the electric conducting structure 114 by the bonding layer 112, so the bonding layer 112 may be disposed between the electrodes 206 of the light-emitting element 200 and the electric conducting structure 114. In some embodiments, the material of the electric conducting structure 114 may comprise any suitable electric conducting materials, such as aluminum (Al), copper (Cu), tungsten (W), titanium (Ti), tantalum (Ta), titanium nitride (TiN), tantalum nitride (TaN), nickel silicide (NiSi), cobalt silicide (CoSi), tantalum carbide (TaC), silicon tantalum nitride (TaSiN), carbon tantalum nitride (TACN), titanium aluminide (TiAl), aluminum titanium nitride (TiAlN), other suitable electric conducting materials, or a combination of the above.

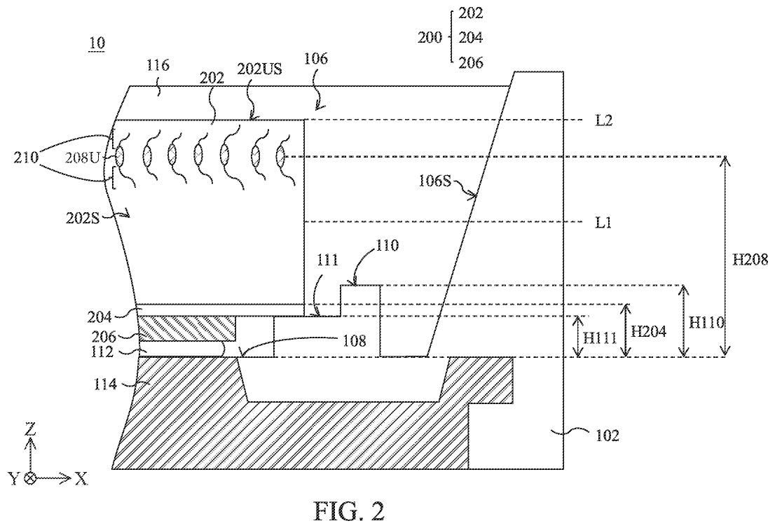

Further, FIG. 2 illustrates a partial enlargement view of FIG. 1 in accordance with some embodiments. Take reference to FIG. 2, the step portion 110 comprises a height H110 relative to the base plane 108, and the first cutting trace 208 comprises a height H208 relative to the base plane 108. The height H208 of the first cutting trace 208 is greater than the height H110 of the step portion 110. The roughened region 210 in the proximity of the first cutting trace 208 of the side wall 202S of the substrate 202 of the light-emitting element 200 has a rougher surface compared to the region outside the first cutting trace 208 of the side wall 202S and the region outside the roughened region 210. Since it is easier for the emitted light of the semiconductor stack 204 to be emitted from the roughened region 210, the light-emitting amount is greater on the roughened region 210. The roughness can be analyzed, by Atomic Force Microscope (AFM), for example, to further measure the average surface roughness (Ra) or the root mean square roughness (RMS). Rendering the height H208 of the first cutting trace 208 greater than the height H110 of the step portion 110 can prevent the light emitted from the first cutting trace 208 and the roughened region 210 nearby of the light-emitting element 200 from being blocked by the step portion 110 of the main body 102, impacting the overall light-emitting effect of the light-emitting package 10.

As shown in FIG. 2, the first level L1 is defined at the fifty percent thickness of the substrate 202, and the second level L2 is defined at a top surface 202US of the substrate 202 which is far from the base plane 108. The second level L2 is higher than the first level L1. In some embodiments, the first cutting trace 208 and the roughened region 210 is disposed between the first level L1 and the second level L2. If the position where the first cutting trace 208 locates is too low, e.g., at the position lower than the first level L1, the laser beam may be focused at the position closer to the semiconductor stack 204 during the dicing process and may cause damage to the semiconductor stack 204 during the dicing process. In that case, a portion of the light emitted from the light-emitting element 200 may be blocked by the step portion 110, and the luminous efficiency of the light-emitting package 10 may be reduced.

Further, in accordance with some embodiments, the interface between the substrate 202 and the semiconductor stack 204 of the light-emitting element 200 comprises a height H204 relative to the base plane 108. As shown in FIG. 2, the height H110 of the step portion 110 is between the height H204 of the semiconductor stack 204 and the height H208 of the first cutting trace 208. In one embodiment, the height H110 of the step portion 110 is between the height H208 of the first cutting trace 208 and the height of the interface disposed between the semiconductor stack 204 and the electrodes 206 relative to the base surface 108.

In FIG. 1 and FIG. 2, in accordance with some embodiments, the main body 102 may further comprise another step portion 111. The step portion 111 may be used for supporting the light-emitting element 200, so that the light-emitting element 200 can be in line with a desired position and bonded to the base plane 108. In some embodiments, the light-emitting element 200 may contact the step portion 111 and be separated from the step portion 110. According to some embodiments, the step portion 111 comprises a height Hill relative to the base plane 108. The height H204 of the semiconductor stack 204 is between the height H111 of the step portion 111 and the height H110 of the step portion 110.

In some embodiments, as shown in FIG. 1 and FIG. 2, the light-emitting package 10 may further comprise a reflective layer (not shown in the figures). The reflective layer is disposed on the inner wall 106S of the cavity 106. The reflective layer can reflect the light emitted from the light-emitting element 200 toward the light-emitting face of the light-emitting package 10, such as the topmost surface of the light-emitting package 10 along the Z-axis direction, to further enhance the overall luminous efficiency of the light-emitting package 10. In one embodiment, the reflective layer may comprise some reflective material and matrix. For instance, the reflective layer may be a silicone-based mixture containing reflective material or an epoxy-based mixture containing reflective material. For instance, in some embodiments, the reflective material may be titanium oxide (TiO₂), aluminum oxide (Al₂O₃), silicon oxide (SiOₓ), zirconium oxide, magnesium oxide, zinc oxide, boron nitride, or a combination of the above. In one embodiment, during the manufacturing processes of the light-emitting package 10, the step portion 110 can stop the reflective layer on the inner wall 106S from overflowing or collapsing toward the light-emitting element 200.

Referring to FIG. 1 and FIG. 2 again, according to some embodiments, the light-emitting package 10 may further comprise packaging material. The packaging material is filled in the cavity 106, formed on the light-emitting element 200 and encapsulates the light-emitting element 200 to protect the light-emitting element 200. In some embodiments, the packaging material 116 may comprise a matrix. In another embodiment, the packaging material 116 comprises the matrix and other material. For instance, the packaging material 116 comprises the matrix and wavelength conversion material mixed in the matrix to form a wavelength conversion structure, whereby the wavelength conversion material comprises optical filter material or phosphors.

According to some embodiments, the material of the matrix may comprise transparent polymer material. Specifically, the transparent polymer material is provided with high transmittance for light with wavelength from 200 nm to 1100 nm. For instance, the aforementioned polymer material may comprise polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), epoxy, acrylic, silicone, or a combination of the above.

Further, FIG. 3 illustrates a cross-sectional view of the detailed structure of the light-emitting element 200 in accordance with some embodiments. In some embodiments, the substrate 202 of the light-emitting element 200 may be a growth substrate used for epitaxially growing the semiconductor stack 20 in the following process. For instance, the material of the substrate 202 comprise silicon, silicon carbide (SiC), sapphire, aluminum nitride (AlN), or gallium nitride (GaN) for epitaxially growing aluminum indium gallium nitride (AlInGaN) semiconductor stack, or gallium arsenide (GaAs) or gallium arsenide (GaP) for epitaxially growing aluminum gallium indium phosphide (AlGaInP) semiconductor stack. In one embodiment, the substrate 202 comprises sapphire. In addition, in accordance with some embodiments, the substrate 202 may be transparent or translucent. Specifically, in the embodiment of transparent substrate 202, the material of the substrate 202 is provided with a light transmittance greater than eighty five percent for light with wavelength between 200 nm to 1100 nm, or with a light transmittance greater than ninety two percent in another embodiment. In the embodiment of translucent substrate 202, the material of the substrate 202 is provided with a light transmittance greater than twenty five percent and lower than eighty five percent for light with wavelength between 200 nm to 1100 nm.

Referring to FIG. 3, in accordance with some embodiments, the semiconductor stack 204 of the light-emitting element 200 may comprise a first conductivity type semiconductor layer 204A, light-emitting layer 204B on the first conductivity type semiconductor layer 204A, and a second conductivity type semiconductor layer 204C on the light-emitting layer 204B. The first conductivity type semiconductor layer 204A and the second conductivity type semiconductor layer 204C provide different carriers with different conductivity property respectively, so that the carriers can be combined in the light-emitting layer 204B to emit light. In one embodiment, the first conductivity type semiconductor layer 204A may be an n-type semiconductor layer providing electrons, and the second conductivity type semiconductor layer 204C may be a p-type semiconductor layer providing holes. The first conductivity type semiconductor layer 204A, the light-emitting layer 204B, and the second conductivity type semiconductor layer 204C may comprise group III-V compound semiconductor materials, such as GaN series material, InGaN series material, AlGaN series material, AlInGaN series material, GaP series material, InGaP series material, AlGaP series material, and AlInGaP series material, all of which can be expressed by AlₓIn_{y}Ga_{(1-x-y)}N or AlₓIn_{y}Ga_{(1-x-y)}P, where 0≤x≤1, 0≤y≤1, and (x+y)≤1. According to the property of the materials adopted in the structure, the light-emitting element 200 can emit IR, red, green, blue, near UV, or UV light. For instance, When the material of the first conductivity type semiconductor layer 204A, the light-emitting layer 204B and the second conductivity type semiconductor layer 204C of the semiconductor stack 204 is AlGaInP series material, red light with a wavelength between 610 nm and 650 nm can be emitted. When the material of the first conductivity type semiconductor layer 204A, the light-emitting layer 204B and the second conductivity type semiconductor layer 204C of the semiconductor stack 204 is InGaN series material, blue light with a wavelength between 400 nm and 490 nm or green light with a wavelength between 530 nm and 570 nm can be emitted. When the material of the first conductivity type semiconductor layer 204A, the light-emitting layer 204B and the second conductivity type semiconductor layer 204C of the semiconductor stack 204 is AlGaN series material or AlInGaN series material, UV light with a wavelength between 250 nm and 400 nm can be emitted. Suitable epitaxial growth process can be utilized to deposit the material of the semiconductor stack 204 on the substrate 202, such as metal organic chemical vapor deposition (MOCVD), molecular beam epitaxy (MBE), liquid phase epitaxy (LPE), vapor phase epitaxy (VPE) or a combination of the above. In one embodiment, the semiconductor stack 204 may further comprise a buffer layer (not shown) disposed between the substrate 202 and the first conductivity type semiconductor layer 204A. The buffer layer can relieve lattice mismatch and restrain lattice dislocation so as to improve epitaxy quality. The buffer layer may also include multiple sublayers with the materials including but not limited to GaN, AlGaN, or AlN.

After epitaxially growing the material layer of the semiconductor stack 204, the patterning process can be performed on the material layer of the semiconductor stack 204 to expose the first conductivity type semiconductor layer 204A of the semiconductor stack 204. As shown in FIG. 3, in accordance with some embodiments, the light-emitting element 200 may further comprise an electric conduction contact layer 205 and a first insulating layer 207. The electric conduction contact layer 205 is disposed on the second conductivity type semiconductor layer 204C, and the first insulating layer 207 is disposed on the semiconductor stack 204 and the electric conduction contact layer 205. In some embodiments, the first insulating layer 207 comprises openings 209. The electrodes 206 of the light-emitting element 200 can be filled in the openings 209 for electrically connecting the semiconductor stack 204 (electrically connecting the first conductivity type semiconductor layer 204A and the second conductivity type semiconductor layer 204C as shown in FIG. 3).

According to some embodiments, the electric conduction contact layer 205 of the light-emitting element 200 may comprise some material capable of forming good electric contact (e.g., ohmic contact) with the second conductivity type semiconductor layer 204C. The material of the electric conduction contact layer 205 may comprise thin metal film or transparent electric conducting material, such as metal oxide. The metal oxide may comprise indium tin oxide (ITO), indium zinc oxide (IZO), aluminum zin oxide (AZO), or zinc oxide (ZnO). The material of the thin metal film may comprise nickel, silver, or nickel gold alloy.

According to some embodiments, the material of the electrodes 206 of the light-emitting element 200 may comprise any suitable metallic materials, such as chromium (Cr), titanium (Ti), gold (Au), aluminum (Al), silver (Ag), copper (Cu), tin (Sn), nickel (Ni), rhodium (Rh), tungsten (W), indium (In), platinum (Pt), an alloy or a stack of the aforementioned materials.

In some embodiments, the first insulating layer 207 of the light-emitting element 200 may be structured as a single layer or multiple sublayers. The material of the first insulating layer 207 may comprise silicon oxide, silicon nitride, silicon oxynitride, niobium oxide, hafnium oxide, titanium oxide, magnesium fluoride, aluminum oxide, or a combination of the above. In one embodiment, the first insulating layer 207 may comprise a distributed Bragg reflector (DBR) structure. In detail, the distributed Bragg reflector structure of the first insulating layer 207 may be made by one or more pairs of dielectric materials, each of which has different refractive index and is stacked together. By means of selecting dielectric materials having different refraction indices combined with the design of specific thicknesses, the first insulating layer 207 can reflect light with a specific wavelength. Therefore, the described insulating layer in the specification can be called by “insulative reflecting layer” as well. In some embodiments, the first insulating layer 207 may comprise a combination of the distributed Bragg reflector and other insulative material layer.

According to some embodiments, when the metallic material of the electrodes 206 are selected from aluminum, silver, or metallic material with high reflectivity, combined with a single layer or multiple sublayers distributed Bragg reflector as the first insulating layer 207, an Omni-Directional Reflector (ODR) can be constituted to further enhance the luminous efficiency of the light-emitting element 200 and the light-emitting package 10.

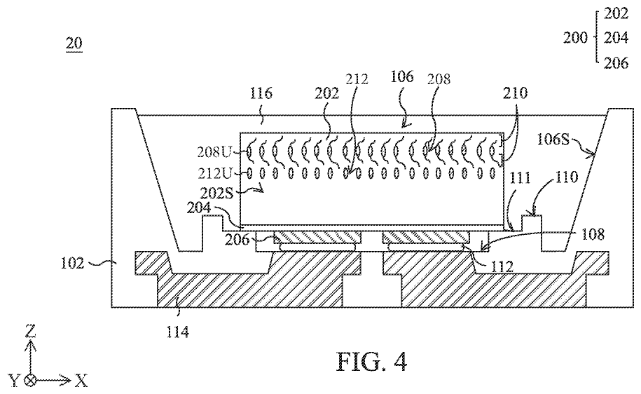

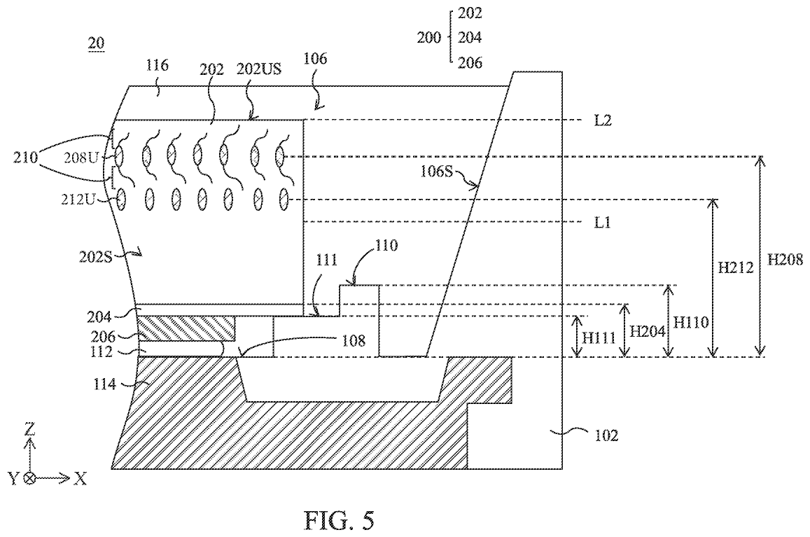

FIG. 4 is a cross-sectional view of the light-emitting package 20 in accordance with some other embodiments, and FIG. 5 is a partial-enlargement view of FIG. 4 in accordance with some other embodiments. It is noted that the light-emitting element 200 in FIG. 4 is illustrated by side view to show the side appearance of the light-emitting element 200 disposed in the light-emitting package 20. The light-emitting package 20 shown in FIG. 4 and FIG. 5 are similar to the light-emitting package 10 shown in FIG. 1 and FIG. 2. However, in the light-emitting package 20, the side wall 202S of the substrate 202 of light-emitting element 200 further comprises a second cutting trace 212. The first cutting trace 208 is disposed between the top surface 202US and the second cutting trace 212. The forming method of the second cutting trace 212 is the same with the forming method of the first cutting trace 208 described above, so no further explanation is given hereunder. The side wall 202S may have a roughened region (not shown in the figures) or may not have any roughened region on the top side, the bottom side, or both of the top side and the bottom side of the second cutting trace 212, and/or between the dotted cutting trace units 208U. Similarly, in accordance with some embodiments, the second cutting trace 212 also comprises a plurality of dotted cutting trace units 212U arranged along a horizontal direction (e.g., the X-axis direction or Y-axis direction of FIG. 4 and FIG. 5). These dotted cutting trace units 212U may be separated and disconnected to each other or partially overlapped and connected to each other. Forming the second cutting trace 212 on the side wall 202S can render the light-emitting element 200 being easily separated from each other during dicing process. Moreover, similar to the nearby region of the first cutting trace 208, the light-emitting element 200 is also provided with high light-emitting amount at the nearby region of the second cutting trace 212. Therefore, a portion of light can be emitted from the position of the second cutting trace 212 and reflected toward the light-emitting face of the light-emitting package 10 by the inner wall 106S of the cavity 106 of the light-emitting package 10.

Referring to FIG. 5, in accordance with some embodiments, the second cutting trace 212 is disposed between the first level L1 (i.e., the height of fifty percent thickness of the substrate 202 relative to the bottom surface of the substrate) and the second level L2 (i.e., the top surface 202US of the substrate 202 that is far from the base plane 108). In addition, in accordance with some embodiments, the second cutting trace 212 is positioned at a height H212 relative to the base plane 108. The height H212 of the second cutting trace 212 may be between the height H110 of the step portion 110 and the height H208 of the first cutting trace 208. If the position of the second cutting trace 212 is too low (e.g., lower than the first level L1), a portion of the light of the light-emitting element 200 may be blocked by the step portion 110, so the luminous efficiency of the light-emitting package 20 may be reduced.

As shown in FIG. 4 and FIG. 5, in the embodiment in which the side wall 202S further comprises the second cutting trace 212, the roughened region 210 is disposed on the top side and the bottom side of the first cutting trace 208, and a portion of the roughened region is disposed between the first cutting trace 208 and the second cutting trace 212. In one embodiment, the second cutting trace 212 can render the roughened region 210, which is produced in the dicing process to the light-emitting element 200, being limited between the second cutting trace 212 and the second level L2 to prevent the texture of the roughened region 210 from extending to the semiconductor stack 201 to further affecting the structural stability of the semiconductor stack 204, preventing the performance of the light-emitting element 200 from being impacted.

In one embodiment, the light-emitting element 200 comprises the substrate 202 shaped in rectangular when viewed from above. The substrate 202 comprises four side walls 202S, i.e., a first pair side walls 202S parallel to a first direction and a second pair side walls 202S vertical to the aforementioned first direction. In one embodiment, the quantity of the cutting trace on the first and second pair side walls 202S may be the same. In another embodiment, the quantity of the cutting trace on the first and second pair side walls 202S may be different. For instance, the first pair side walls comprises the first cutting trace 208, while the second pair side walls comprises the first cutting trace 208 and the second cutting trace 212. In one embodiment, the height H208 of the first cutting trace 208 of the first pair side walls and the second pair side walls may be different relative to the base plane 108. In one embodiment, the thickness of the substrate 202 is between 80 μm to 450 μm. In another embodiment, it is between 120 μm to 250 μm.

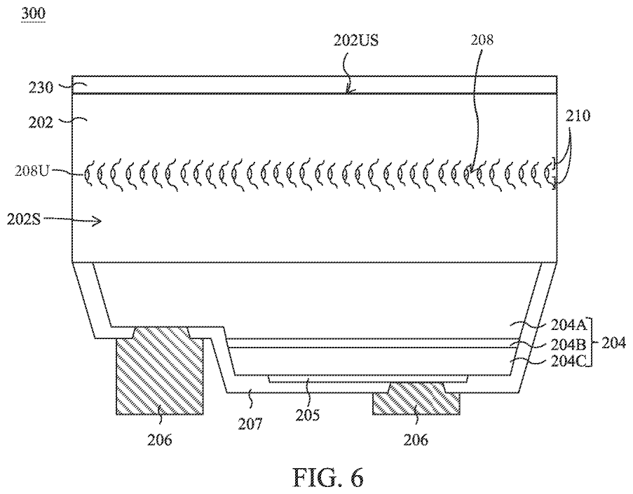

FIG. 6 is a side view of the light-emitting element 300 in accordance with some other embodiments. The light-emitting element 300 of FIG. 6 is similar to the light-emitting element 200 in FIG. 3, but the light-emitting element 300 may further comprise a second insulating layer 230 (also called insulating reflective layer 230). The second insulating layer 230 is disposed on the top surface 202US of the substrate 202. Therefore, as shown in FIG. 6, the first insulating layer 207 and the second insulating layer 230 are disposed on opposite sides of the substrate 202 respectively. The second insulating layer 230 may comprise the material that is the same with or similar to the first insulting layer 207. In some embodiments, the second insulating layer 230 may include a single layer or multiple sublayers like distributed Bragg reflector. The second insulting layer 230 can reflect the light emitted from the semiconductor stack 204 to enhance luminous efficiency.

In addition, as shown in FIG. 6, the first cutting trace 208 of the light-emitting element 300 is disposed at the height relative to a bottom surface of the substrate 202 located in a range of forty percent to sixty percent thickness of the substrate 202. Similarly, in accordance with some embodiments, the side wall 202S of the substrate 202 further comprises the roughened region 210. The roughened region 210 is adjacent to the first cutting trace 208 and disposed on the top side and/or the bottom side of the first cutting trace 208. Further, in some embodiments, the side wall 202S may also further comprise the same second cutting trace described in the aforementioned embodiment (not shown in FIG. 6). The second cutting trace is disposed below the first cutting trace 208 and at the height located in a range of forty percent to sixty percent thickness of the substrate 202 relative to the bottom surface of the substrate 202. A portion of the roughened region 210 may be sandwiched between the first cutting trace 208 and the second cutting trace. In one embodiment, the light-emitting element 300 comprises the second insulating layer 230 on the top surface 202US and the first insulating layer 207 on the surface of the semiconductor stack 204. The light emitted from the semiconductor stack 204 is reflected by the aforementioned first insulating reflective layer 207, and finally most of the light is emitted out of the side wall 202S of the substrate 202. As described above, the nearby region of the first cutting trace 208 is provided with greater light-emitting amount, when most of the light of the light-emitting element 300 is emitted out of the side wall 202, rendering the cutting trace being disposed at the height located in a range of forty percent to sixty percent thickness of the substrate 202 relative to a bottom surface of the substrate can enhance the luminous efficiency of the light-emitting element 300.

It shall be comprehensible that though the light-emitting packages 10, 20 shown in FIGS. 1,2,4, and 5 comprise the light-emitting element 200, the light-emitting element 200 of the light-emitting package 10, 20 may be replaced in lieu of the light-emitting element 300 to lower the possibility of damaging the semiconductor stack 204 and enhance the luminous efficiency of the light-emitting packages 10, 20.

To sum up, in accordance with some embodiments of the disclosure, the light-emitting package comprises the main body, base plane, and the light-emitting element. The main body comprises the step portion, and the light-emitting element comprises the substrate. The side wall of the substrate of the light-emitting element comprises the first cutting trace. The height of the first cutting trace relative to the base plane is greater than the height of the step portion relative to the base plane. The first cutting trace being formed at a higher position of the substrate can avoid damaging the semiconductor stack of the light-emitting element. It also prevents the light penetrated by the first cutting trace from being blocked by the step portion to further impact the luminous efficiency of the light-emitting package.

Although some embodiments of the present disclosure and their advantages have been described in detail, it should be understood that various changes, substitutions and alterations can be made herein without departing from the spirit and scope of the disclosure as defined by the appended claims. For example, it will be readily understood by one of ordinary skill in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A light-emitting package, comprising:
a main body;
a cavity disposed in the main body;
a base plane in the cavity; and
a light-emitting element disposed in the cavity and connected with the base plane, wherein the light-emitting element comprises:
a substrate comprising a side wall, the side wall comprising a first cutting trace; and
a semiconductor stack disposed on the substrate;
wherein the main body comprises a first step portion disposed in the cavity and surrounds the light-emitting element; wherein the first step portion comprises a first height relative to the base plane, the first cutting trace comprises a second height relative to the base plane, and the second height is greater than the first height.

2. The light-emitting package claimed in claim 1, wherein the light-emitting element further comprises:
an electrode connected to the base plane; and
a first insulating layer disposed on the semiconductor stack and comprising an opening; wherein the electrode is filled in the opening to electrically connecting the semiconductor stack.

3. The light-emitting package claimed in claim 1, wherein the side wall further comprises a roughened region; the roughened region is adjacent to the first cutting trance and disposed on a top side and/or a bottom side of the first cutting trace.

4. The light-emitting package claimed in claim 3, wherein the substrate comprises a top surface far from the base plane, a bottom surface, and a height located of fifty percent thickness of the substrate relative to the bottom surface, and the roughened region is disposed between the top surface of the substrate and the height of fifty percent thickness of the substrate relative to the bottom surface.

5. The light-emitting package claimed in claim 1, wherein the substrate comprises a top surface far from the base plane, and the side wall further comprises a second cutting trace; the first cutting trace is disposed between the second cutting trace and the top surface.

6. The light-emitting package claimed in claim 5, wherein the second cutting trace comprises a third height relative to the base plane, and the third height is between the first height and the second height.

7. The light-emitting package claimed in claim 5, wherein the side wall further comprises a roughened region; the roughened region is adjacent to the first cutting trace and disposed on a top side and a bottom side of the first cutting trace; a portion of the roughened region is disposed between the first cutting trace and the second cutting trace.

8. The light-emitting package claimed in claim 5, wherein the substrate comprises a bottom surface and a height of fifty percent thickness of the substrate relative to the bottom surface, and the second cutting trace is disposed between the top surface and the height of fifty percent thickness of the substrate relative to the bottom surface.

9. The light-emitting package claimed in claim 1, wherein the semiconductor stack comprises a fourth height relative to the package base plane; the first height is between the second height and the fourth height.

10. The light-emitting package claimed in claim 9, wherein the main body further comprises a second step portion; wherein the second step portion comprises a fifth height relative to the base plane.

11. The light-emitting package claimed in claim 10, wherein the semiconductor stack is supported by the second step portion; the fourth height of the semiconductor stack is between the fifth height of the second step portion and the first height of the first step portion.

12. The light-emitting package claimed in claim 11, wherein the main body comprises an inner wall; wherein the light-emitting package further comprises a recess disposed between the inner wall and the first step portion.

13. The light-emitting package claimed in claim 11, wherein the main body comprises an inner wall; wherein the light-emitting package further comprises a reflective layer on the inner wall.

14. The light-emitting package claimed in claim 12, wherein the side wall further comprises a roughened region and the first cutting trace comprises a top side and a bottom side; the roughened region is adjacent to the first cutting trance and disposed on the top side and/or the bottom side of the first cutting trace.

15. The light-emitting package claimed in claim 1, wherein the roughened region is horizontally arranged.

16. The light-emitting package claimed in claim 1, further comprises an electric conducting structure; the electric conducting structure is embedded in the main body, and the base plane is on the electric conducting structure.

17. A light-emitting element, comprising:
a substrate comprising a first surface, a second surface opposite to the first surface, and a side wall;
a semiconductor stack disposed on the first surface;
a first insulting reflective layer disposed on the semiconductor stack and having an opening;
a second insulating reflective layer disposed on the second surface; and
an electrode disposed on the first insulating reflective layer and filled in the opening to electrically connecting the semiconductor stack;
wherein the side wall comprises a first cutting trace and the substrate comprises a bottom surface and a height located in a range of forty to sixty percent thickness of the substrate relative to the bottom surface; wherein the first cutting trace is disposed at the height within the range of forty to sixty percent thickness of the substrate relative to the bottom surface.

18. The light-emitting element claimed in claim 17, wherein the side wall further comprises a second cutting trace, and the first cutting trace is between the second surface of the substrate and the second cutting trace.

19. The light-emitting element claimed in claim 17, wherein the side wall further comprises a roughened region and the first cutting trace comprises a top side and a bottom side; the roughened region is disposed on the top side and/or the bottom side of the first cutting trace.

20. The light-emitting element claimed in claim 18, wherein the substrate comprises a bottom surface and a height of fifty percent thickness of the substrate relative to the bottom surface, and the roughened region is between the second surface of the substrate and the height of fifty percent thickness of the substrate relative to the bottom surface.
